(19) United States
(12) Patent Application Publication
(10) Pub. No.: US 2025/0149417 A1
(43) Pub. Date: May 8, 2025

(54) SINGLE-SIDED DIRECT COOLED POWER MODULE

(71) Applicant: Navitas Semiconductor Limited, Dublin (IE)

(72) Inventor: Oseob Jeon, Seoul (KR)

(73) Assignee: Navitas Semiconductor Limited, Dublin (IE)

(21) Appl. No.: 18/934,929

(22) Filed: Nov. 1, 2024

Related U.S. Application Data
(60) Provisional application No. 63/596,178, filed on Nov. 3, 2023.

(51) Int. Cl. H01L 23/498; H01L 21/48; H01L 23/00; H01L 23/13; H01L 23/473; H01L 25/07

(52) U.S. Cl. CPC H01L 23/49811; H01L 21/4853; H01L 23/13; H01L 23/49822; H01L 23/49844; H01L 23/473; H01L 24/40; H01L 24/48; H01L 24/73; H01L 25/072; H01L 2224/40225; H01L 2224/48139; H01L 2224/48157; H01L 2224/73221; H01L 2924/10272

(57) ABSTRACT

A power module includes a substrate that includes an electrically insulating layer. A first electrically conducting region, a second electrically conducting region, and a third electrically conducting region are each disposed on the electrically insulative layer. The electrically conducting regions are electrically isolated from each other. A plurality of high-side power switches is disposed on and electrically coupled to the first electrically conducting region. A plurality of first connectors is coupled between the plurality of high-side power switches and the second electrically conductive region. A plurality of low-side power switches is disposed on and electrically coupled to the second electrically conductive region. A plurality of second connectors is coupled between the plurality of low-side power switches and the third electrically conductive region. A power lead is coupled to the first electrically conductive region via a spacer.

### CROSS-REFERENCE TO RELATED APPLICATIONS

This application claims priority to U.S. provisional patent application Ser. No. 63/596,178, for “SINGLE-SIDED DIRECT COOLED POWER MODULE” filed on Nov. 3, 2023, the contents of which are incorporated herein by reference in their entirety for all purposes.

### FIELD

The described embodiments relate generally to power electronics containing one or more semiconductor dies. More particularly, the present embodiments relate to single-sided direct cooled power electronics with semiconductor dies.

### BACKGROUND

Currently there are a wide variety of power modules for power management. The power modules can include multiple semiconductor switches. Designs of existing power modules can include a narrow contact area between Direct Current (DC) voltage lead frame connections and a power module substrate. The narrow contact area can create high stray inductance due to low current flow and high electrical resistance through the contact. Additionally, transfer molded power modules can include signal pins attached to a side of a molded body of the power module, which can lead to short creepage distances between the signal pins.

### SUMMARY

In some embodiments, a power module comprises a substrate that includes an electrically insulating layer. A first electrically conducting region, a second electrically conducting region, and a third electrically conducting region are each disposed on the electrically insulative layer. The electrically conducting regions are electrically isolated from each other. A plurality of high-side power switches is disposed on and electrically coupled to the first electrically conducting region. A plurality of first connectors is coupled between the plurality of high-side power switches and the second electrically conductive region. A plurality of low-side power switches is disposed on and electrically coupled to the second electrically conductive region. A plurality of second connectors is coupled between the plurality of low-side power switches and the third electrically conductive region. A power lead is coupled to the first electrically conductive region via a spacer.

In some embodiments, the spacer comprises an electrically conductive metal.

In some embodiments, the power lead is substantially planar, and the spacer is soldered between the power lead and the first electrically conductive region.

In some embodiments, a thickness of the spacer can be greater than a thickness of the power lead.

In some embodiments, the power lead is a first DC+ lead and the spacer is a first spacer, and the power module further comprises a second DC+ lead coupled to the first electrically conductive region via a second spacer.

In some embodiments, the power module further comprises a DC− lead disposed between the first DC+ lead and the second DC+ lead. The DC− lead is electrically coupled to the third electrically conductive region.

In some embodiments, the power module further comprises a power output lead electrically coupled to the second electrically conductive region.

In some embodiments, each of the plurality of high-side power switches and each of the plurality of low-side power switches are silicon carbide transistors.

In some embodiments, an electronic module comprises a substrate that comprises an electrically insulative layer. The substrate further comprises an electrically conductive layer that defines first, second, and third conductive regions and is formed on the electrically insulative layer. The first, second, and third conductive regions are electrically insulated from each other. The second electrically conductive region defines an opening and the third electrically conductive region is disposed within the opening. A plurality of high-side power switches is disposed on and electrically coupled to the first electrically conducting region. A plurality of low-side power switches is disposed on and electrically coupled to the second electrically conductive region. A power lead is coupled to the first electrically conductive region via a spacer.

In some embodiments, the spacer of the electronic module comprises an electrically conductive metal.

In some embodiments, the power lead of the electronic module is substantially planar, and the spacer is soldered between the power lead and the first electrically conductive region.

In some embodiments, a thickness of the spacer of the electronic module can be greater than a thickness of the power lead.

In some embodiments, the power lead of the electronic module is a first DC+ lead and the spacer is a first spacer, and the power module further comprises a second DC+ lead coupled to the first electrically conductive region via a second spacer.

In some embodiments, the electronic module further comprises a DC− lead disposed between the first DC+ lead and the second DC+ lead. The DC− lead is electrically coupled to the third electrically conductive region.

In some embodiments, the electronic module further comprises a power output lead electrically coupled to the second electrically conductive region.

In some embodiments, each of the plurality of high-side power switches and each of the plurality of low-side power switches of the electronic module are silicon carbide transistors.

In some embodiments, each of the plurality of high-side power switches is connected to each of the plurality of low-side power switches in a half-bridge configuration.

In some embodiments, a method for forming an electronic module comprises forming an insulative layer of a substrate. The method further comprises, forming first, second, and third electrically conductive regions on a top surface of a substrate. Each of the first, second, and third electrically conductive regions are electrically insulated from each other. The second electrically conductive region defines an opening and the third electrically conductive region is disposed within the opening. Additionally, the method comprises attaching a plurality of high-side power switches to the first electrically conductive region. The method comprises electrically coupling a plurality of first connectors between the plurality of high-side power switches and the second electrically conductive region. The method further comprises electrically coupling a plurality of low-side power switches to the second electrically conductive region. Additionally, the method comprises electrically coupling a plurality of second connectors between the plurality of low-side power switches and the third electrically conductive region. The method comprises coupling a power lead to the first electrically conductive region via a spacer.

In some embodiments, the spacer described in the method comprises an electrically conductive metal.

In some embodiments, a thickness of the spacer described in the method is greater than a thickness of the power lead.

### BRIEF DESCRIPTION OF THE DRAWINGS

FIG. 1 is a semi-transparent assembly drawing of a power module;

FIG. 2 is a semitransparent plan view of a lead frame portion of a power module;

FIG. 3A is a perspective view assembly drawing of an assembled power module;

FIG. 3B is an assembly drawing of a first cross section of an assembled power module;

FIG. 3C is an assembly drawing of a second cross section of an assembled power module;

FIG. 4A is an isometric drawing of a top portion of an assembled power module, according to embodiments of the disclosure;

FIG. 4B illustrates a cross-sectional view of a portion of the power module shown in FIG. 4A;

FIG. 4C illustrates a similar cross-sectional view of the power module as shown in FIG. 4B;

FIG. 5A is a top view assembly drawing of a molded and assembled power module;

FIG. 5B is a side view assembly drawing of a molded and assembled power module;

FIG. 5C is a top perspective view assembly drawing of a molded and assembled power module without recesses;

FIG. 5D is a bottom view assembly drawing of a molded and assembled power module;

FIG. 5E is a bottom perspective view assembly drawing of a molded and assembled power module;

FIG. 6A is a top view assembly drawing of a six-pack direct cooling power assembly;

FIG. 6B is a top perspective view assembly drawing of a six-pack direct cooling power assembly;

FIG. 6C is a bottom perspective view assembly drawing of a six-pack direct cooling power assembly;

FIG. 7A is a perspective view assembly drawing of components for a six-pack direct cooling module; and

FIG. 7B is a perspective view assembly drawing of an assembled six-pack direct cooling module.

### DETAILED DESCRIPTION

In some embodiments a high-power AC to DC power module includes a lead frame with DC power leads designed to electrically connect to the power module in a manner that reduces inductance by maximizing surface areas of contact for reduced resistance and increased current flow. The lead frame can include two positive DC power leads and a negative DC power lead. The negative DC power lead can be wide and include a bar that can make contact with multiple metal clip surfaces on the power module. The two positive DC power leads can include tabs that connect with spacers on the power module. Each spacer can be positioned beneath a tab of a positive power lead and entire top surfaces of the spacers can make electrical contact with the tab to provide a wide conductive path and reduce inductance. In some embodiments the power module may be used for an electrical vehicle including but not limited to a traction module that provides power to a traction motor or an AC to DC converter that convers AC energy to DC energy used to charge one or more batteries.

The lead frame can also include pin holders that can accept signal pins after molding. The lead frame can be molded with a recessed mold design that protects and covers cavities of the pin holders during the molding process. After the molding process, signal pins can be inserted into the pin holders. The signal pins can be press-fit pins.

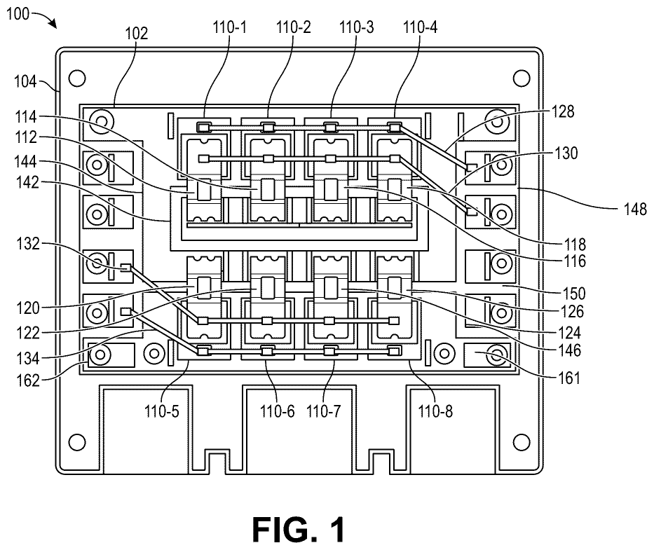

FIG. 1 is a semi-transparent assembly drawing of a power module 100, according to embodiments of the disclosure. The power module 100 can referred to as an electronic module. The power module 100 includes a substrate 102 in a molded case 104. Power switches 110 are soldered (or sintered) to the substrate 102. In some embodiments the power switches 110 are silicon carbide, gallium nitride or silicon field effect transistors (FET) s and they are soldered to the substrate 102 electrically coupling their drains to the substrate 102. Four low-side power switches 110-1, 110-2, 110-3 and 110-4 are connected in parallel with drain terminals soldered to substrate region 144. Although four low-side power switches are shown in FIG. 1, the power module 100 can include any number of low-side power switches, including a single low-side power switch. Four high-side power switches 110-5, 110-6, 110-7, and 110-8 are connected in parallel with drain terminals soldered to substrate region 146. Although four high-side power switches are shown in FIG. 1, the power module 100 can include any number of high-side power switches, including a single high-side power switch. The substrate regions 144 and 146 are electrically conductive and are electrically isolated from each other. In some embodiments, substrate 102 can be a direct-bonded copper (DBC), insulated metal substrate (IMS) or other suitable high thermal conductivity substrate.

One end of a conductive clip 112 is soldered to the top (source) of power switch 110-1 and the other end of conductive clip 112 is soldered to substrate region 142. The substrate region 144 can define an opening and the substrate region 142 can be disposed in the opening. One end of a conductive clip 114 is soldered to the top of power switch 110-2 and the other end of conductive clip 114 is soldered to substrate region 142. One end of a conductive clip 116 is soldered to the top of power switch 110-3 and the other end of conductive clip 116 is soldered to substrate region 142. One end of a conductive clip 118 is soldered to the top of power switch 110-4 and the other end of conductive clip 118 is soldered to substrate region 142. Substrate region 142 is electrically conductive and electrically isolated from substrate regions 144 and 146. The substrate regions 142, 144, and 146 can be formed on an electrically insulative layer 148.

One end of a conductive clip 120 is soldered to the top (source) of power switch 110-5 and the other end of conductive clip 120 is soldered to substrate region 144 (switch node). One end of a conductive clip 122 is soldered to the top (source) of power switch 110-6 and the other end of conductive clip 122 is soldered to substrate region 144. One end of a conductive clip 124 is soldered to the top (source) of power switch 110-7 and the other end of conductive clip 124 is soldered to substrate region 144. One end of a conductive clip 126 is soldered to the top (source) of power switch 110-8 and the other end of conductive clip 126 is soldered to substrate region 144.

Clips 112, 114, 116, 118 are all a similar length so that the current paths for current entering and leaving the low-side power switches are equal in length. Clips 120, 122, 124 and 126 are all a similar length so that the current paths for current entering and leaving the high-side power switches are equal in length. Sense conductors 128 and 130 are used as Kelvin sense wires for power switches 110-1 to 110-4. Sense conductors 132 and 134 are used as Kelvin sense wires for switches 110-5 through 110-8. In some embodiments the clips are first attached and the sense wires are subsequently attached. A negative thermal coefficient (NTC) thermal sensor 150 is attached to the substrate 102. The conductive clips can be referred to as connectors. For example, clips 112, 114, 116, and 118 can be called first connectors or second connectors. Similarly, clips 120, 122, 124, and 126 can be called second connectors or first connectors.

In some embodiments the power module 100 is configured in a half-bridge configuration or arrangement, however other suitable electrical configurations can be used. The input voltage DC (+) is electrically coupled to the drains of high-side power switches 110-5 through 110-8 which are all connected in parallel. The sources of high-side power switches 110-5 through 110-9 are coupled with the drains of low-side power switches 110-1 through 110-4 to form the switch node of substrate region 144. The sources of low-side power switches 110-1 through 110-4 are coupled to ground DC (−) and are all coupled in parallel.

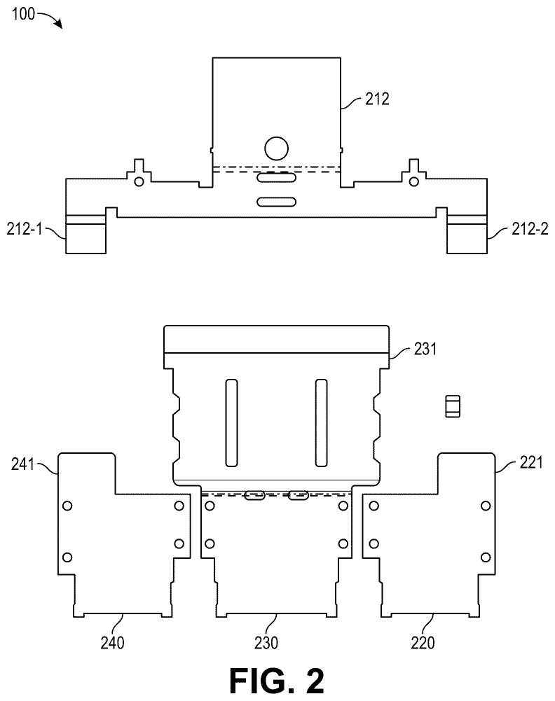

The input voltage DC (+) power leads (shown in FIG. 2) can be electrically coupled to substrate region 146 via first spacer 162 and second spacer 161. The first and second spacers 162, 161 can be formed from an electrically conductive metal, such as copper. A thickness of the first spacer 162 can be equal to, greater than, or less than a thickness of the input voltage DC (+) power leads. Similarly, a thickness of the second spacer 161 can be equal to, greater than, or less than a thickness of the input voltage DC (+) power leads. Although two spacers are shown in FIG. 1, the power module 100 can include any number of spacers including a single spacer. The first and second spacers 162, 161 can be soldered between the input voltage DC (+) power leads and substrate region 146. Rectangular cross-sections of first and second spacers 162, 161 are shown in FIG. 1. The cross-sections of the spacers can take on any 2-D shape, such as circular, elliptical, square, hexagonal, etc.

FIG. 2 is a semitransparent plan view of a lead frame portion of a power module 100, according to embodiments of the disclosure. The lead frame connects a substrate 102 (see FIG. 1) of the power module 100 to DC (+) voltage using a right plus power lead 220 and a left plus power lead 240. Right plus power lead 220 includes tab 221 that is connected to the substrate region 146 (see FIG. 1) via first spacer 162 (see FIG. 1). Right plus power lead 220 can be substantially planar. Left plus power lead 240 includes tab 241 that is connected to the substrate region 146 via second spacer 161 (see FIG. 1). Left plus power lead 240 can be substantially planar. DC (−) is connected to substrate region 142 (see FIG. 1) using the negative power lead 230. Negative power lead 230 has a power lead formed end 231 that connects to the substrate region 142 (see FIG. 1). Current in the DC (+) direction, through the plus power leads 220, 240 is in the opposite direction of the DC (−) current direction through the negative power lead 230. The two current paths are in close proximity reducing the parasitic/stray inductance. Reducing parasitic inductance improves the switching characteristics. Output lead 212 is connected to the substrate region 144 (see FIG. 1). The output lead 212 is connected to the substrate using tabs 212-1 and 212-2.

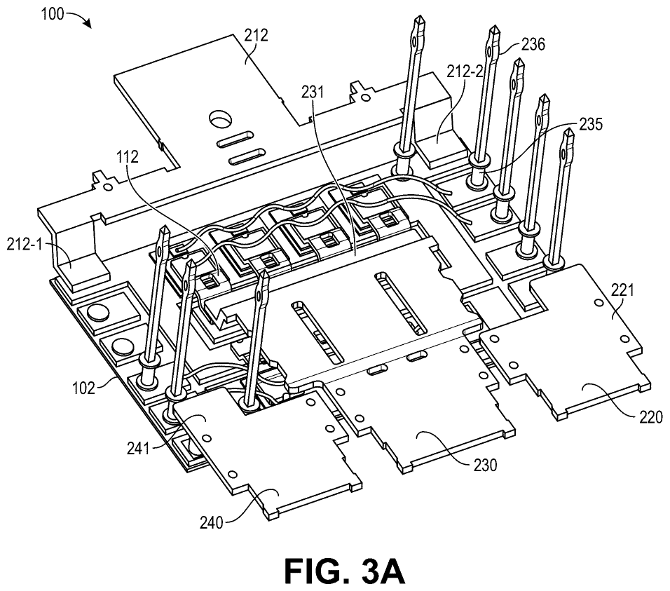

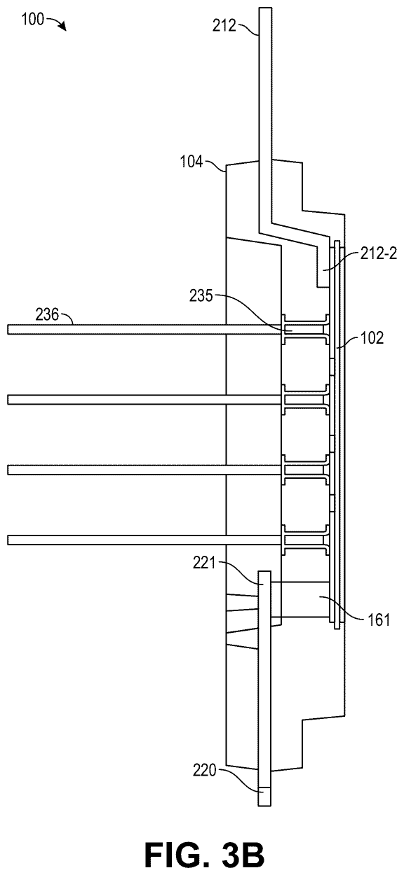

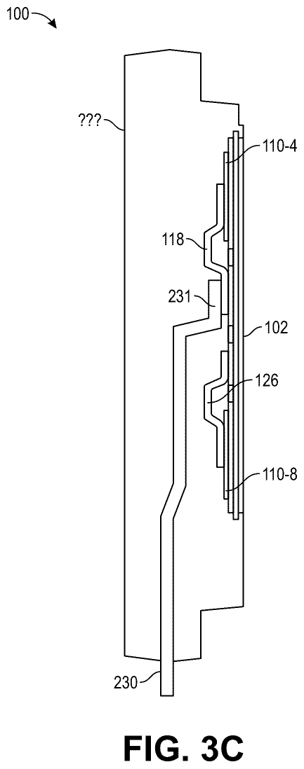

FIG. 3A is a perspective view assembly drawing of an assembled power module 100. The lead frame connects the power module 100 to DC (+) voltage using a right plus power lead 220 and a left plus power lead 240. Right plus power lead 220 includes tab 221 that is connected to the substrate region 146 (see FIG. 1) through direct contact with second spacer 161 (see FIG. 1, the second spacer 161 is hidden from view in FIG. 3A). The second spacer 161 can be directly under tab 221 and an entire top surface of the second spacer 161 can be in direct contact with tab 221, allowing the right plus power lead 220 to be substantially planar. Left plus power lead 240 includes tab 241 that is connected to the substrate region 146 (see FIG. 1) through direct contact with first spacer 162 (see FIG. 1, the first spacer 162 is partially hidden in FIG. 3A). The first spacer 162 can be directly under tab 241 and an entire top surface of the first spacer 162 can be in direct contact with tab 241, allowing left plus power lead 240 to be substantially planar. DC (−) is connected to substrate region 142 (see FIG. 1) using the negative power lead 230. Negative power lead 230 has a formed end 231 that connects to the substrate region 142 via direct contact with clips (for simplicity only clip 112 is labeled in FIG. 3A). Current in the DC (+) direction, through the plus power leads 220, 240 is in the opposite direction of the DC (−) current direction through the negative power lead 230. The two current paths are in close proximity reducing the parasitic inductance. Reducing parasitic inductance may improve the switching characteristics such as speed, transient control, etc. Output lead 212 is connected to the substrate region 144 (see FIG. 1). The output lead 212 is connected to the substrate using tabs 212-1 and 212-2. The power module 100 can also include signal pins 236 and signal pin holders 235. Although eight signal pins and eight signal pin holders are shown in FIG. 3A, for simplicity only one of each is labeled. The power module 100 can include any number of signal pins and signal pin holders, including one of each. The signal pins can be electrically conductive pins and each signal pin can be electrically coupled to gate terminals of each of the high-side power switches 110-5, 110-6, 110-7, and 110-8 (see FIG. 1) or to gate terminals of each of the low-side power switches 110-1, 110-2, 110-3, and 110-4 (see FIG. 1). At least one of the signal pins can be a kelvin sense terminal for the high-side power switches 110-5, 110-6, 110-7, and 110-8 and at least one of the signal pins can be a kelvin sense terminal for the low-side power switches 110-1, 110-2, 110-3, and 110-4. Although two plus power leads and a single negative power lead are shown in FIG. 3A, the power module 100 can include any number of plus power leads and negative power leads and an arrangement of power leads can vary. For example, the power module 100 can include a single plus power lead positioned between two negative power leads.

FIG. 3B is an assembly drawing of a first cross section of an assembled power module 100. The assembled power module 100 can include a power assembly that is over molded (e.g., encapsulated) with an electrically insulative mold material (e.g., insulative encapsulant), formed into molded case 104. Right plus power lead 220 includes tab 221 that is connected to the substrate region 146 (see FIG. 1) of the substrate 102 through direct contact with second spacer 161. A portion of the right plus power lead 220 is outside of the molded case 104. An opening in the molded case 104 can be formed above the tab 221 to allow a push-pin to press down on a multi-layer stack (e.g., substrate 102 plus spacer 161 and tab 221) during a molding process forming a contact with the cavity that prevents mold flashes. The opening can be filled with molding compound after the molding process is complete.

Output lead 212 is connected to the substrate region 144 (see FIG. 1). The output lead 212 is connected to the substrate 102 using tabs 212-1 (see FIGS. 2) and 212-2. The power module 100 can also include signal pins 236 and signal pin holders 235, for simplicity only one of each is labeled. Each signal pin 236 can include a bottom portion that is covered by the mold case 104, and a top portion that is outside the mold case 104 and above a recess formed in the mold case.

FIG. 3C is an assembly drawing of a second cross section of an assembled power module 100. The assembled power module 100 can include a molded case 104. DC (−) is connected to substrate region 142 (see FIG. 1) of the substrate 102 using the negative power lead 230. Negative power lead 230 has a formed end 231 that connects to the substrate region 142 via direct contact with clips, such as clip 118. A portion of the negative power lead 230 can lie outside the molded case. One end of the conductive clip 118 is soldered to the top of power switch 110-4 and the other end of conductive clip 118 is soldered to substrate region 142 of the substrate. One end of a conductive clip 126 is soldered to the top (source) of power switch 110-8 and the other end of conductive clip 126 is soldered to substrate region 144 (see FIG. 1).

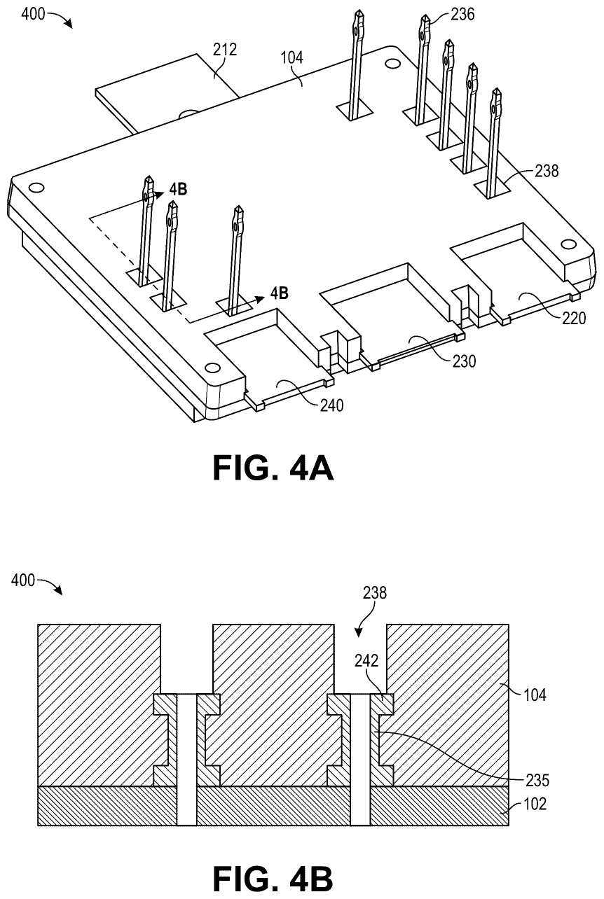

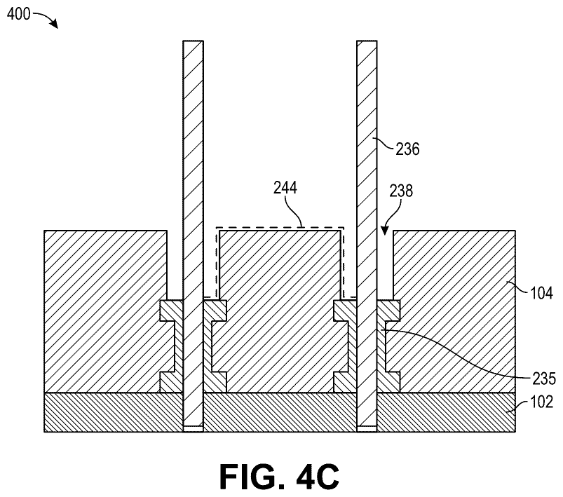

FIG. 4A is an isometric drawing of a top portion of an assembled power module 100, according to embodiments of the disclosure. The power module 100 includes recessed pin regions providing improved pin-to-pin creepage performance, as described in more detail below. As shown in FIG. 4A, power module 100 includes a plurality of recesses 238 that are formed around the signal pins 236 (although eight signal pins are shown in FIG. 4A, only one is labeled for simplicity). Each of the plurality of recesses 238 can form at or define a bottom exterior surface of the power module 100.

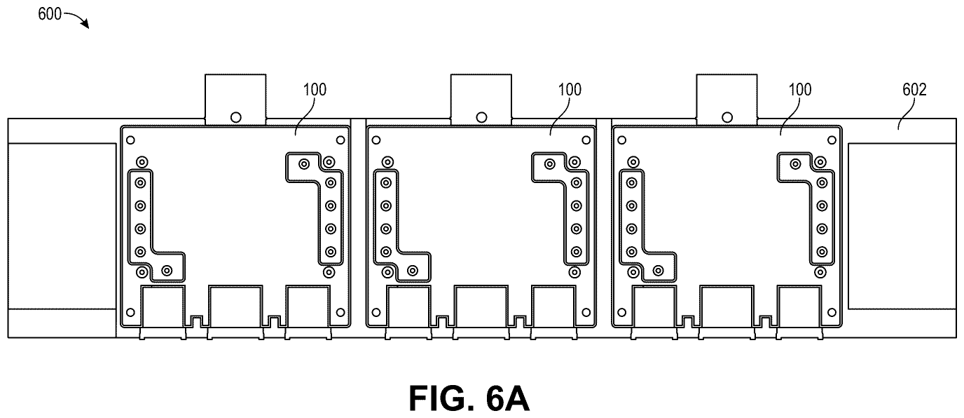

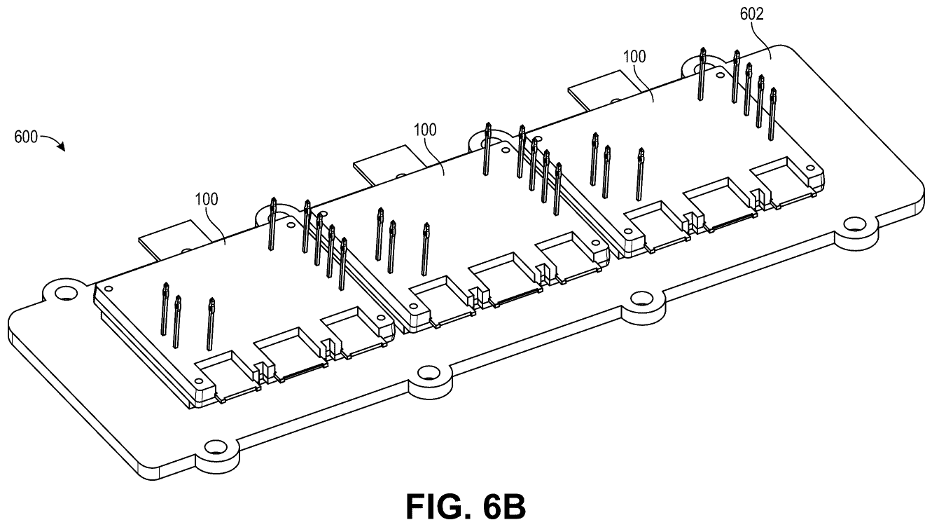

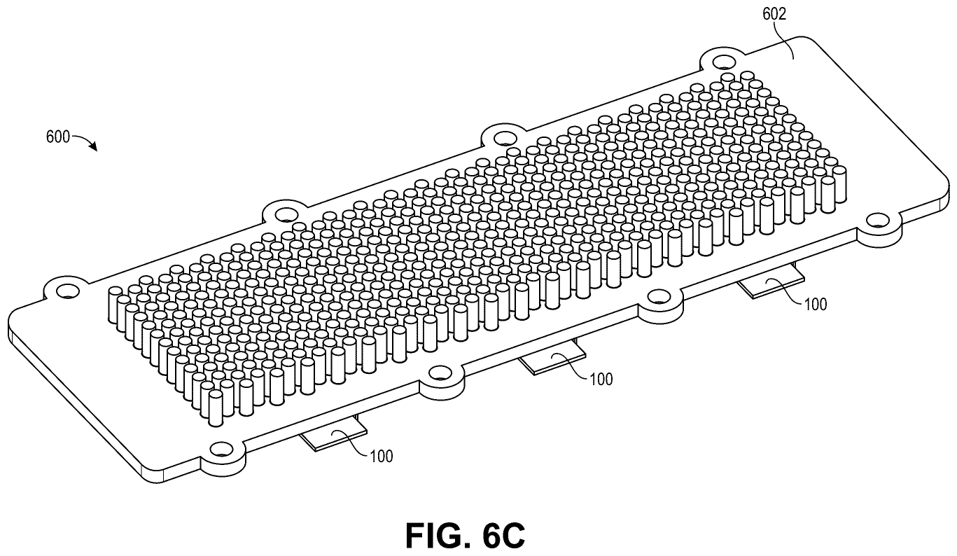

FIG. 4B illustrates a cross-sectional view of a portion of power module 100 shown in FIG. 4A. As shown in FIG. 4B, a recess 238 is aligned with each pin region. FIG. 6B does not show the pins for clarity. Each recess 238 is aligned with a pin holder 235 which may be a metallic structure that is attached to the substrate 102 via soldering, welding, gluing or other suitable means. To form the recesses a mold tool may include an extension that seals against the pin holder 235 such that mold compound 104 does not flow into the pin opening 242. The pin holder 235 and recesses 238 may have any suitable dimensions and may be modified to increase or decrease creepage clearance.

FIG. 4C illustrates a similar cross-sectional view as shown in FIG. 4B, however in FIG. 4C the pins 236 are shown as well as a creepage path 244 between adjacent pins 236. As shown in FIG. 4C the recesses 238 significantly increase the distance of the creepage path 244 as compared a design that does not have the recesses 238.

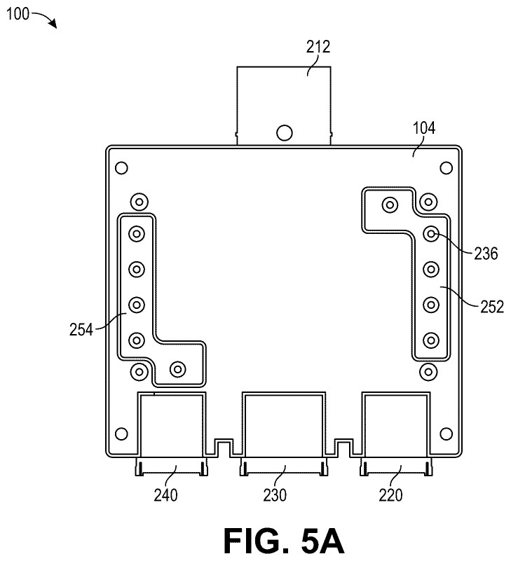

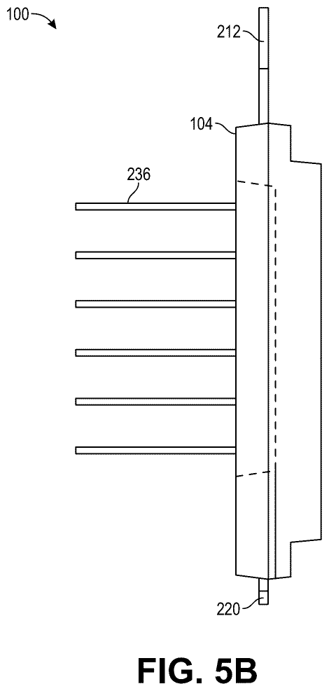

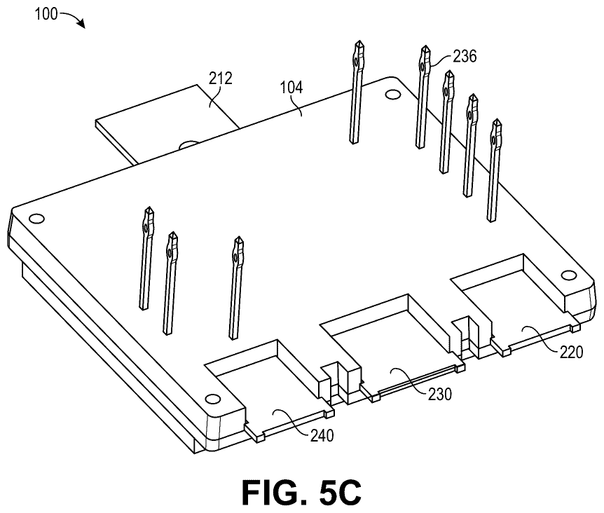

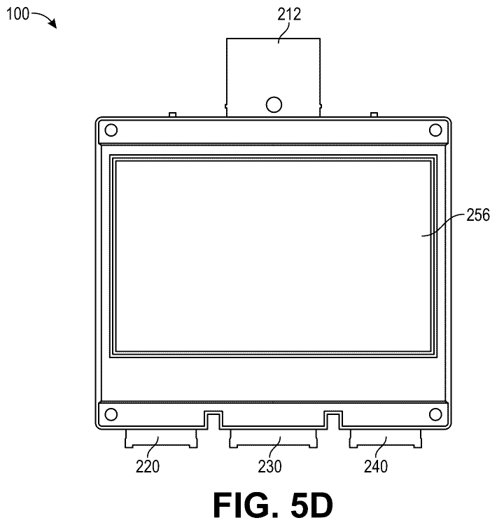

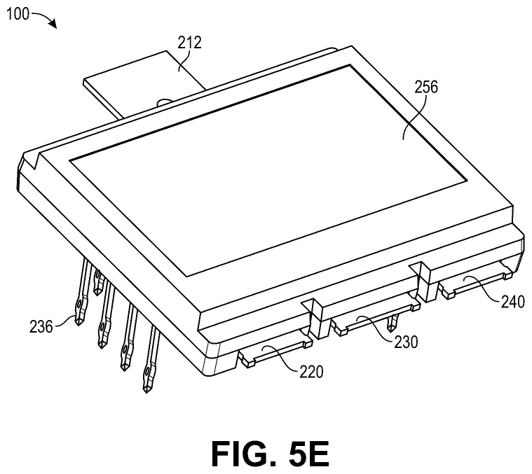

FIG. 5A is a top view assembly drawing of a molded and assembled power module 100. The assembly drawing shows exposed portions of the lead frame including a right plus power lead 220, a left plus power lead 240, a negative power lead 230, and an output lead 212. The top view also shows a molded case 104 of the assembled power module 100. The molded case 104 includes two recessed regions 252 and 254. The recessed regions 252 and 254 can be formed during the molding process and used to seal pin holder apertures so mold material does not get into the apertures during the molding process. After the molding process, the pins 236 can be inserted into the pin holders. Although several pins 236 are shown in FIG. 2, only one pin is labeled for clarity.

FIG. 5B is a side view assembly drawing of a molded and assembled power module 100. The side view also shows molded case 104 of the assembled power module 100. The molded case 104 can include recessed regions. After the molding process, the pins 236 can be inserted into the pin holders.

FIG. 5C is a top perspective view assembly drawing of a molded and assembled power module 100 without recesses, according to embodiments of the disclosure. In some examples, molded case 104 of the power module may not include recesses. After the molding process, signal pins can be inserted into openings in the molded case 104. The openings may have an area that is similar to a cross-sectional area of the signal pins.

FIG. 5D is a bottom view assembly drawing of a molded and assembled power module 100. The bottom view assembly drawing shows exposed portions of the lead frame including a right plus power lead 220, a left plus power lead 240, a negative power lead 230, and an output lead 212. The top view also shows an exposed bottom portion 256 of a substrate 102 (see FIG. 1) of the assembled power module 100. The exposed bottom portion 256 can be placed in direct contact (e.g., via thermal interface material, silver sintering, etc.) with a heat sink or liquid cooled housing.

FIG. 5E is a bottom perspective view assembly drawing of a molded and assembled power module 100. The bottom perspective view assembly drawing shows signal pins 236 and exposed portions of the lead frame including a right plus power lead 220, a left plus power lead 240, a negative power lead 230, an output lead 212, and an exposed bottom portion 256 of a substrate 102 (see FIG. 1) of the power module 100.

FIG. 6A is a top view assembly drawing of a six-pack direct cooling power assembly 600. The six-pack direct cooling power assembly 600 can include three assembled power modules 100 positioned side by side and each fastened to a heatsink 602. In some examples, the heatsink 602 is cooled by a liquid or air. FIGS. 6B and 6C show a top perspective assembly drawing and a bottom perspective assembly drawing of the six-pack direct cooling power assembly 600, respectively.

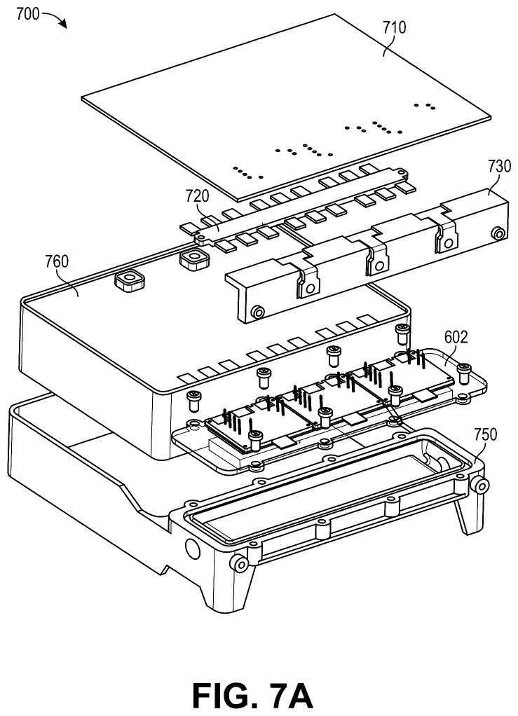

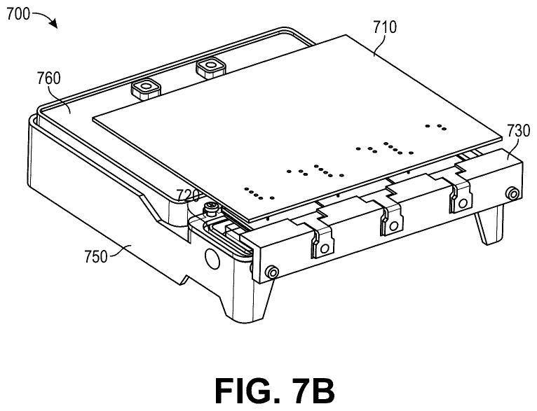

FIG. 7A is a perspective view assembly drawing of components for a six-pack direct cooling module 700. The components can include a liquid cooling housing 750, a DC-bus capacitor 760 that fits in an open portion of the liquid cooling housing 750, and a power assembly 600 that can be fastened to a top portion of the liquid cooling housing 750. The six-pack direct cooling module 700 can also include a DC busbar 720 that can be attached to a portion of the capacitor 760 and a portion of the power assembly 600. An AC busbar 730 of the six-pack direct cooling module 700 can be attached to a portion of the power assembly 600 and the liquid cooling housing 750. A control board 710 can be placed as an upper surface of the six-pack direct cooling module 700. FIG. 7B is a perspective view assembly drawing of an assembled six-pack direct cooling module 700.

In some embodiments switches and/or diodes may be fabricated with gallium nitride GaN, silicon carbide SiC, and/or silicon. In various embodiments one or more of the switches may be field-effect switches including but not limited to enhancement mode and depletion mode switches.

One of ordinary skill in the art will appreciate that various features and aspects of the power module with balanced current can be changed, modified and manipulated which are within the scope of this disclosure.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the switch in use and/or operation in addition to the orientation depicted in the figures. For example, if the switch in the figures is turned over, elements described as a “bottom” surface can then be oriented “above” other elements or features. The switch can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A power module comprising:
a substrate comprising:
an electrically insulative layer;
a first electrically conductive region disposed on the electrically insulative layer;
a second electrically conductive region disposed on the electrically insulative layer and electrically isolated from the first electrically conductive region; and
a third electrically conductive region disposed on the electrically insulative layer and electrically isolated from each of the first and the second electrically conductive regions;
a plurality of high-side power switches disposed on and electrically coupled to the first electrically conductive region;
a plurality of first connectors electrically coupled between the plurality of high-side power switches and the second electrically conductive region;
a plurality of low-side power switches disposed on and electrically coupled to the second electrically conductive region;
a plurality of second connectors electrically coupled between the plurality of low-side power switches and the third electrically conductive region; and
a power lead coupled to the first electrically conductive region via a spacer.

2. The power module of claim 1, wherein the spacer comprises an electrically conductive metal.

3. The power module of claim 1, wherein the power lead is substantially planar, and wherein the spacer is soldered between the power lead and the first electrically conductive region.

4. The power module of claim 1, wherein a thickness of the spacer is greater than a thickness of the power lead.

5. The power module of claim 1, wherein the power lead is a first DC+ lead and the spacer is a first spacer, and wherein the power module further comprises a second DC+ lead coupled to the first electrically conductive region via a second spacer.

6. The power module of claim 5, further comprising a DC− lead disposed between the first DC+ lead and the second DC+ lead, the DC− lead electrically coupled to the third electrically conductive region.

7. The power module of claim 1, further comprising a power output lead electrically coupled to the second electrically conductive region.

8. The power module of claim 1, wherein each of the plurality of high-side power switches and each of the plurality of low-side power switches are silicon carbide transistors.

9. An electronic module comprising:
a substrate comprising:
an electrically insulative layer; and
an electrically conductive layer formed on the electrically insulative layer and defining first, second, and third electrically conductive regions that are each electrically insulated from each other, wherein the second electrically conductive region defines an opening, and wherein the third electrically conductive region is disposed within the opening;
a plurality of high-side power switches disposed on and electrically coupled to the first electrically conductive region;
a plurality of low-side power switches disposed on and electrically coupled to the second electrically conductive region; and
a power lead coupled to the first electrically conductive region via a spacer.

10. The electronic module of claim 9, wherein the spacer comprises an electrically conductive metal.

11. The electronic module of claim 9, wherein the power lead is substantially planar, and wherein the spacer is soldered between the power lead and the first electrically conductive region.

12. The electronic module of claim 9, wherein a thickness of the spacer is greater than a thickness of the power lead.

13. The electronic module of claim 9, wherein the power lead is a first DC+ lead and the spacer is a first spacer, and wherein the electronic module further comprises a second DC+ lead coupled to the first electrically conductive region via a second spacer.

14. The electronic module of claim 13, further comprising a DC− lead disposed between the first DC+ lead and the second DC+ lead, the DC− lead electrically coupled to the third electrically conductive region.

15. The electronic module of claim 9, further comprising a power output lead electrically coupled to the second electrically conductive region.

16. The electronic module of claim 9, wherein each of the plurality of high-side power switches and each of the plurality of low-side power switches are silicon carbide transistors.

17. The electronic module of claim 9, wherein each of the plurality of high-side power switches is connected to each of the plurality of low-side power switches in a half-bridge configuration.

18. A method of forming an electronic module, the method comprising:
forming an insulative layer of a substrate;
forming first, second, and third electrically conductive regions on a top surface of the substrate, wherein each of the first, second, and third electrically conductive regions are each electrically insulated from each other, wherein the second electrically conductive region defines an opening, and wherein the third electrically conductive region is disposed within the opening;
attaching a plurality of high-side power switches to the first electrically conductive region;
electrically coupling a plurality of first connectors between the plurality of high-side power switches and the second electrically conductive region;
electrically coupling a plurality of low-side power switches to the second electrically conductive region;
electrically coupling a plurality of second connectors between the plurality of low-side power switches and the third electrically conductive region; and
electrically coupling a power lead to the first electrically conductive region via a spacer.

19. The method of claim 18, wherein the spacer comprises an electrically conductive metal.

20. The method of claim 18, wherein a thickness of the spacer is greater than a thickness of the power lead.
